(19) United States
(12) Patent Application Publication
(10) Pub. No.: US 2010/0259888 A1
(43) Pub. Date: Oct. 14, 2010

(54) THERMAL SPREADER FOR HEAT PIPE COOLERS AND WATER COOLERS

(76) Inventors: Vadim Anatolievich Pomytkin, Kirov (RU); Igor Anatolievich Pomytkin, Moscow (RU); Pavel Vasilievich Verteletsky, Moscow (RU)

Correspondence Address: NOTARO, MICHALOS & ZACCARIA P.C., 100 DUTCH HILL ROAD, ORANGEBURG, NY, 10962, US

(21) Appl. No.: 12/678,373

(22) PCT Filed: Sep. 17, 2007
(86) PCT No.: PCT/RU2007/000501

§ 371 Date: May 5, 2010

(51) Int. Cl. G06F 1/20; H05K 7/20; F28D 15/04; F28D 15/00

(52) U.S. Cl. 361/679.47; 361/697; 165/104.26; 165/104.31

(57) ABSTRACT

This invention relates to thermal spreader incorporated into heat pipe coolers and water coolers for electronic components, said spreader having optimal aspect ratio T/(√S)≧0.17 to provide optimal parameters of thermal resistance and lowering noise created by these coolers supplying by operating fans, where T is thickness of said thermal spreader and (√S) is square root of the surface area of the first surface of said thermal spreader. Further, the invention relates to electronic systems comprising said thermal spreader with optimal aspect ratio T/(√S)≧0.17 to provide better thermal management of electronic components incorporated into these electronic systems.

### TECHNICAL FIELD

The present invention relates to cooling elements for dissipating heat from an electronic component in electronic devices.

### BACKGROUND OF THE INVENTION

Electronic devices generate heat during normal operation. It is known in electronic equipment to provide cooling systems to keep the electronic component within a range of prescribed operating temperature. Cooling systems of different types including heat pipe coolers and water coolers are used for cooling electronic components. An active fan is often mounted on top of the heat pipe and water coolers to transfer heat from a heat source to the ambient air. Overall thermal resistance of heat pipe and water coolers depends on both design of the cooler and airflow produced by the fan.

Some cooling systems comprise a thermally conductive base or thermal spreader that spreads heat from the microprocessor to a heat dissipating element such as heat pipe and water cooler, and the heat dissipating element dissipate the heat to the air stream. We found that there is an optimal aspect ratio of the thermal spreader to provide optimal heat transfer through the thermal spreader and, thus, minimize thermal resistance of heat pipe coolers and water coolers. This ratio is T/(√S)≧0.17, where T is thickness of said thermal spreader and (√S) is square root of the surface area of the surface of said thermal spreader. The thermal spreader of this optimal ratio T/(√S)≧0.17 is unknown from the art and has never been used to decrease thermal resistance of heat pipe coolers and water coolers. Because of minimizing thermal resistance of coolers by the use of the thermal spreader having the ratio T/(√S)≧0.17, it is now possible to decrease air flow generated by operating fan and nevertheless keep the electronic component within a range of prescribed operating temperature. Accordingly, it is now possible to reduce fan rotation speed and, thus, to reduce noise generated by operating fan, since the noise of operating fan is proportional to the fan rotation speed.

### BRIEF DESCRIPTION OF THE DRAWINGS

FIG. 1 is a perspective view of a thermal spreader of the invention according to some embodiments.

FIG. 2A is a perspective view of a heat pipe cooler of the invention according to some embodiments.

FIG. 2B is a cross-sectional view of a heat pipe cooler of the invention according to some embodiments.

FIG. 3A is a perspective view of a water cooler of the invention according to some embodiments.

FIGS. 3B and 3C are cross sectional views of the water block according to some embodiments.

FIG. 4 is a schematic side view of an electronic system according to some embodiments, which incorporates the heat pipe cooler of FIG. 2.

FIG. 5 is a schematic side view of an electronic system according to some embodiments, which incorporates the water cooler of FIG. 3.

FIG. 6 is a perspective view of heat pipe cooler used in measurements of dependence of thermal resistance and noise levels on the ratio T/(√S) of the thermal spreader.

FIG. 7 is a graph of change of thermal resistance of heat pipe cooler of FIG. 6 with operating fan versus ratio T/(√S) of the thermal spreader according to some embodiments.

FIG. 8 is a graph of change of noise generated by operating fan of heat pipe cooler of FIG. 6 versus ratio T/(√S) of the thermal spreader according to some embodiments.

### DETAILED DESCRIPTION OF THE INVENTION

The present invention provides a thermal spreader having a first surface to be thermally coupled to an electronic component and an opposing second surface to be thermally coupled to a heat dissipation device selected from the group consisting of a heat pipe cooler and a water cooler, wherein a ratio T/(√S)≧0.17, where T is thickness of said thermal spreader and (√S) is square root of the surface area of the first surface of said thermal spreader.

In some embodiments, the thermal spreader of the invention is manufactured from thermally conductive material, such as, but not limited to, copper, silver, aluminium, and alloys thereof, and graphite.

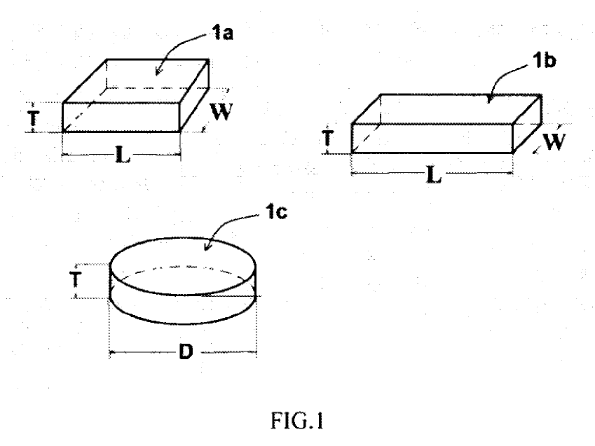

FIG. 1 is a perspective view of a thermal spreader of the invention according to some embodiments. The embodiments of the thermal spreader 1 include, but are not limited to, thermal spreaders 1a, 1b, and 1c. All such thermal spreaders have a first surface and an opposing second surface, wherein a ratio T/(√S)≧0.17, where T is thickness of said thermal spreader and (√S) is square root of the surface area of the first surface of said thermal spreader. For the thermal spreaders 1a and 1b, the surface area of the rectangle first surface is calculated by equation S=L·W, where L is length and W is width of the spreader. For the thermal spreader 1c, the surface area of the circular first surface is calculated by equation S=πD²/4, where D is diameter of the thermal spreader.

Further, the present invention provides a heat pipe cooler for an electronic component comprising: (1) a thermal spreader having a first surface to be thermally coupled to an electronic component and an opposing second surface; (2) at least one heat pipe thermally coupled to said second surface of said thermal spreader; (3) a plurality of fins fixed to said heat pipe; and (4) a fan for supplying the heat dissipating element with ambient air, wherein a ratio T/(√S)≧0.17, where T is thickness of said thermal spreader and (√S) is square root of the surface area of the first surface of said thermal spreader.

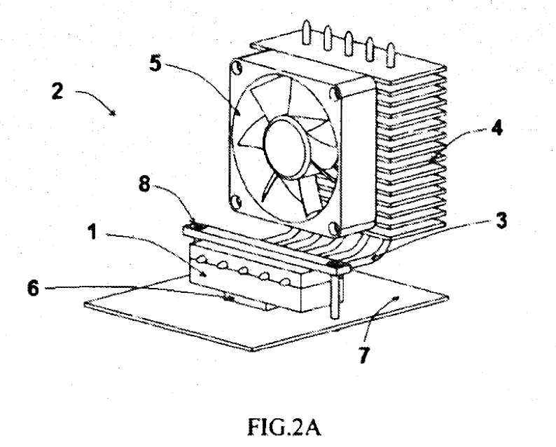

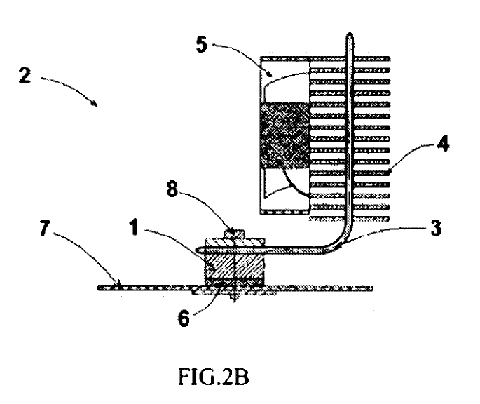

FIG. 2A is a perspective view and FIG. 2B is a cross-sectional view of a heat pipe cooler of the invention according to some embodiments. The cooler 2 comprises the thermal spreader 1 having a ratio T/(√S)≧0.17, where T is thickness of said thermal spreader and (√S) is square root of the surface area of the first surface of said thermal spreader. The cooler 2 also comprises a plurality of heat pipes 3 are thermally coupled to the thermal spreader 1; a plurality of fins 4 mounted on said heat pipes; and the fan 5 for supplying the fins 4 with ambient air. The heat pipe cooler 2 is thermally coupled to an electronic component 6 mounted on a mounting frame 7. The screws 8 secure the heat sink 1 onto the electronic component 6.

Further, the present invention provides a water cooler for an electronic component comprising: (1) a thermal spreader having a first surface to be thermally coupled to an electronic component and an opposing second surface; (2) a water block thermally coupled to said second surface of the thermal spreader to transfer a heat from said thermal spreader; (3) a radiator connected with water block by water pipes; (4) a fan for supplying radiator with ambient air; and (5) a pump for forcing water through the cooling circuit consisting of the water block and the radiator, said pump is connected by water pipes with the water block and the radiator, wherein a ratio T/(√S)≧0.17, where T is thickness of said thermal spreader and ('IS) is square root of the surface area of the first surface of said thermal spreader.

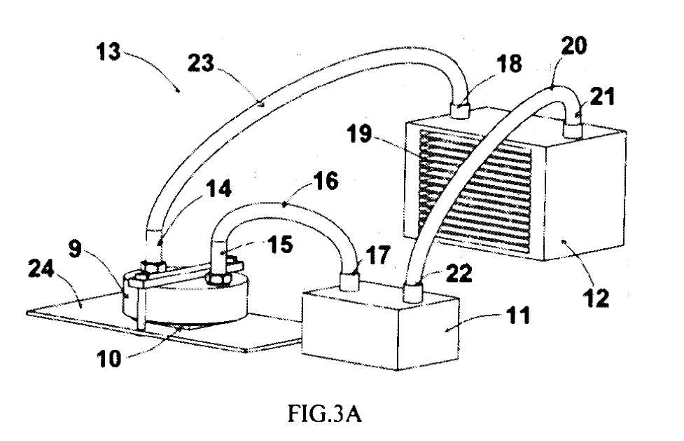

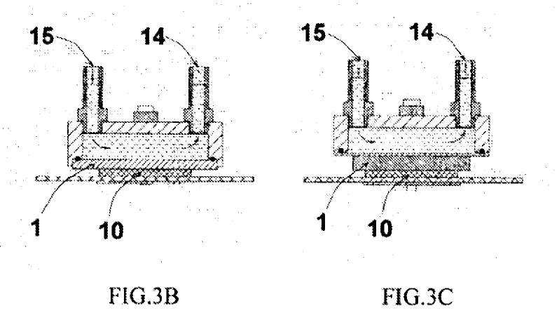

FIG. 3A is a perspective view of a water cooler of the invention according to some embodiments. The water cooler 13 includes a thermal spreader 1 thermally coupled to an electronic component 10 mounted on a mounting frame 24, a water block 9 thermally coupled to the thermal spreader to transfer heat from the thermal spreader 1, a water pump 11, and a radiator 12. The water block 9 has a water outlet 14 and a water inlet 15. A pipe 16 is connected between the water inlet 15 and a water outlet 17 of the water pump 11. Another pipe 23 is connected between the water outlet 14 and a water inlet 18 of the radiator 12. The radiator 12 is composed of multiple fins 19. A pipe 20 is connected between a water outlet 21 of the cooler 12 and a water inlet 22 of the water pump 11. Thus, a cooling circuit of the water cooler 13 is built. In application, colder water is fed into the water block 9 from the water pump 11. After heat exchange, the water is heated by electronic component 10 through the thermal spreader 1 into warmer water. The warmer water which flows into the radiator 12 will be cooled down. Thereby, the colder water then flows back to the water pump 11 to supply the water circulation. FIGS. 3B and 3C are cross sectional views of the water block 9 according to some embodiments. Heat generated from the electronic component 10 is conducted to the water of the water block 9 via the thermal spreader 1 having a ratio T/(√S)≧0.17, where T is thickness of said thermal spreader and (√S) is square root of the surface area of the first surface of said thermal spreader. The cooler water flows into the water inlet 15 and further flows through the water outlet 14. Such that, the water is heated by the electronic component 10 to take away the heat of the electronic component 10.

Further, the present invention provides an electronic system comprising: a substrate; an electronic component mounted on the substrate; a heat pipe cooler for an electronic component comprising: (1) a thermal spreader having a first surface to be thermally coupled to an electronic component and an opposing second surface; (2) at least one heat pipe thermally coupled to said second surface of said thermal spreader; (3) a plurality of fins fixed to said heat pipe; and (4) a fan for supplying the heat dissipating element with ambient air, wherein a ratio T/(√S)≧0.17, where T is thickness of said thermal spreader and (VS) is square root of the surface area of the first surface of said thermal spreader. Preferably, the substrate is a circuit board. Preferably, the electronic component is selected from the group consisting of a microprocessor and a graphics processor. Preferably, the system is selected from the group consisting of a personal computer and media center.

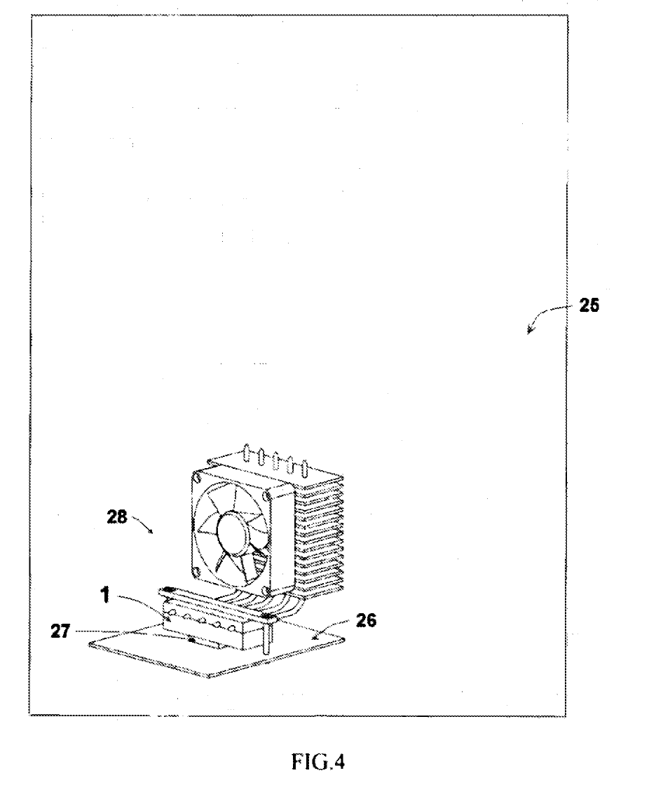

FIG. 4 is a schematic side view of an electronic system according to some embodiments, which incorporates the heat pipe cooler of FIG. 2. The electronic system 25 includes the substrate 26, the electronic component 27 mounted on the substrate 26, and the heat pipe cooler 28 comprising a thermal spreader 1 thermally coupled to an electronic component, the thermal spreader having a ratio T/(√S)≧0.17, where T is thickness of said thermal spreader and (√S) is square root of the surface area of the first surface of said thermal spreader.

Further, the present invention provides an electronic system comprising: a substrate; an electronic component mounted on the substrate; water cooler for an electronic component comprising: (1) a thermal spreader having a first surface to be thermally coupled to an electronic component and an opposing second surface; (2) a water block thermally coupled to said second surface of the thermal spreader to transfer a heat from said thermal spreader; (3) a radiator connected with water block by water pipes; (4) a fan for supplying radiator with ambient air; and (5) a pump for forcing water through the cooling circuit consisting of the water block and the radiator, said pump is connected by water pipes with the water block and the radiator, wherein a ratio T/(√S)≧0.17, where T is thickness of said thermal spreader and (√S) is square root of the surface area of the first surface of said thermal spreader.

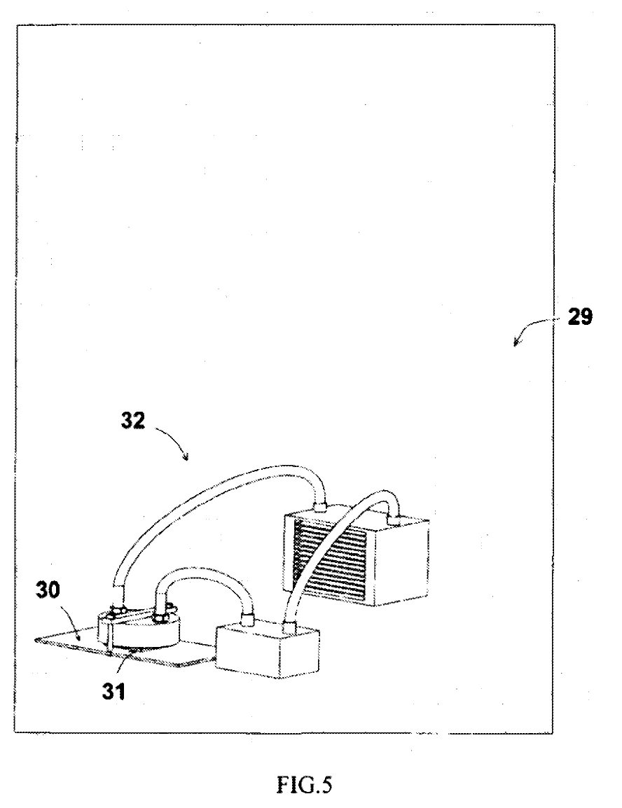

FIG. 5 is a schematic side view of an electronic system according to some embodiments, which incorporates the water cooler of FIG. 3. The electronic system 29 includes the substrate 30, the electronic component 31 mounted on the substrate 30, and the water cooler 32 comprising a thermal spreader 1 thermally coupled to an electronic component, the thermal spreader having a ratio T/(√S)≧0.17, where T is thickness of said thermal spreader and ('IS) is square root of the surface area of the first surface of said thermal spreader.

In some embodiments, the electronic systems 25 and 29 are selected from the group consisting of a personal computer and media center.

In some embodiments, the electronic component may be a conventional packaged IC (integrated circuit). For example, the electronic component, may be a processor such as any type of computational circuit, including but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), or any other type of processor or processing circuit.

The electronic systems 25 and 29 may also include a number of other components which are not shown in the drawing. These components are include, but are not limited to, a chip set and/or a communication circuit which may be functionally coupled to the electronic component, a digital switching circuit, a radio frequency (RF) circuit, a memory circuit, a custom circuit, an application-specific integrated circuit (ASIC), an amplifier, an external memory in the form of one or more memory elements, RAM (random access memory) and/or ROM (read only memory), one or more hard drives and/or one or more drives that handle removable media such as floppy diskettes, compact disks (CDs), digital video disks (DVDs), and so forth all of these components may be functionally coupled to the electronic component.

Still other components (not shown) may be included in the electronic systems 25 and 29 such as a display device, one or more speakers, and a keyboard and/or controller, which can include a mouse, trackball, game controller, speech recognition device or any other device that permits a user to input information into and/or receive information from the electronic systems. Each of these devices, too, may be functionally coupled to the electronic component.

It should be understood that the electronic systems 25 and 29 need not be a personal computer, but may alternatively be a server computer or a game device.

Because of the use of the thermal spreader having the ratio T/(√S)≧0.17, it is now possible to decrease thermal resistance of heat pipe coolers and water pipe coolers. Because of minimizing thermal resistance of coolers of the invention by the use of the thermal spreader having the ratio T/(√S)≧0.17, it is now possible to decrease air flow generated by operating fan and nevertheless keep the electronic component within a range of prescribed operating temperature. Accordingly, it is now possible to reduce fan rotation speed and, thus, to reduce noise generated by operating fan, since the noise of operating fan is proportional to the fan rotation speed.

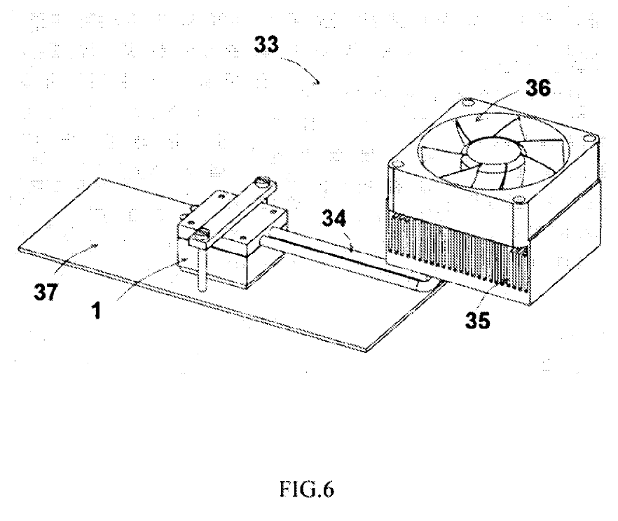

FIG. 6 is a perspective view of heat pipe cooler used in measurements of dependence of thermal resistance and noise levels on the ratio T/(√S) of the thermal spreader. The cooler 33 comprises the thermal spreader 1; two heat pipes 34 thermally coupled to the thermal spreader 1; a plurality of fins 35 mounted on heat pipes 34; and the fan 36 for supplying the fins 35 with ambient air. The cooler 33 is thermally coupled to a heat source mounted on a mounting frame 37.

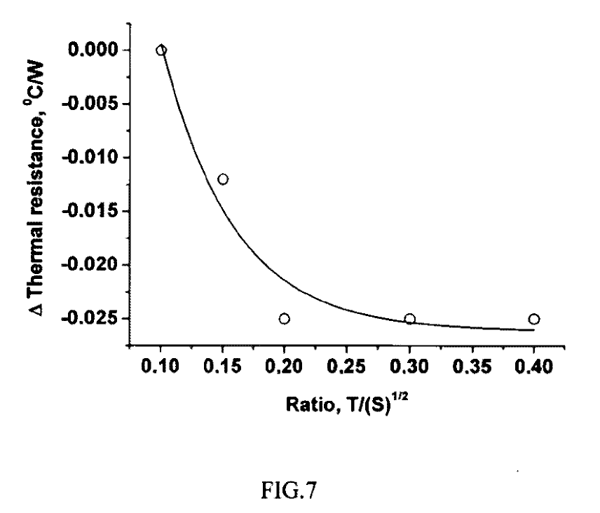

FIG. 7 is a graph of change of thermal resistance of heat pipe cooler of FIG. 6 with operating fan versus ratio T/(VS) of the thermal spreader according to some embodiments. The thermal resistance of the heat pipe cooler was is measured for the thermal spreader 1 of variable height and constant the length and the width, and under otherwise equal conditions. As found, desirable low values of the thermal resistance is achieved when the ratio T/(√S)≧0.17. Thus, the thermal resistance of the heat pipe cooler is minimized with the thermal spreader of optimal ratio T/(√S).

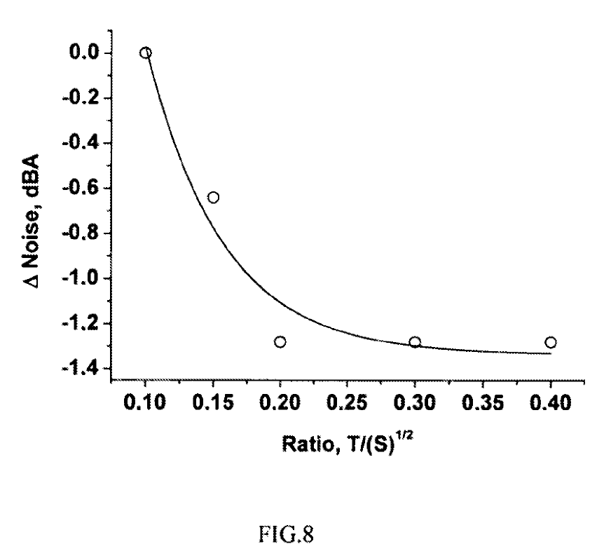

FIG. 8 is a graph of change of noise generated by operating fan of heat pipe cooler of FIG. 6 versus ratio T/(√S) of the thermal spreader according to some embodiments. The noise created by operating fan was measured under the fixed thermal resistance of 0.6° C./watt. The noise value was regulated by rotation speed of operating fan 36. The thermal spreader 1 of variable height and constant the length and the width was used. As found, desirable low values of the noise is achieved when the ratio T/(√S)≧0.17. Thus, the noise of operating heat pipe cooler can be minimized with the thermal spreader of optimal ratio T/(√S).

The several embodiments described herein are solely for the purpose of illustration and are not intended to limit the scope of the invention in any way. The various features described herein need not all be used together, and any one or more of those features may be incorporated in a single embodiment. Therefore, persons skilled in the art will recognize from this description that other embodiments may be practiced with various modifications and alterations.

We claim:

1. A thermal spreader having a first surface to be thermally coupled to an electronic component and an opposing second surface to be thermally coupled to a heat dissipation device selected from the group consisting of a heat pipe cooler and a water cooler, wherein a ratio T/(√S)≧0.17, where T is thickness of said thermal spreader and (√S) is square root of the surface area of the first surface of said thermal spreader.

2. A heat pipe cooler for an electronic component comprising: (1) a thermal spreader having a first surface to be thermally coupled to an electronic component and an opposing second surface; (2) at least one heat pipe thermally coupled to said second surface of said thermal spreader; (3) a plurality of fins fixed to said heat pipe; and (4) a fan for supplying the heat dissipating element with ambient air, wherein a ratio T/(√S)≧0.17, where T is thickness of said thermal spreader and (√S) is square root of the surface area of the first surface of said thermal spreader.

3. A water cooler for an electronic component comprising: (1) a thermal spreader having a first surface to be thermally coupled to an electronic component and an opposing second surface; (2) a water block thermally coupled to said second surface of the thermal spreader to transfer a heat from said thermal spreader; (3) a radiator connected with water block by water pipes; (4) a fan for supplying radiator with ambient air; and (5) a pump for forcing water through the cooling circuit consisting of the water block and the radiator, said pump is connected by water pipes with the water block and the radiator, wherein a ratio T/(√S)≧0.17, where T is thickness of said thermal spreader and (√S) is square root of the surface area of the first surface of said thermal spreader.

4. An electronic system comprising: a substrate; an electronic component mounted on the substrate; a heat pipe cooler for an electronic component comprising: (1) a thermal spreader having a first surface to be thermally coupled to an electronic component and an opposing second surface; (2) at least one heat pipe thermally coupled to said second surface of said thermal spreader; (3) a plurality of fins fixed to said heat pipe; and (4) a fan for supplying the heat dissipating element with ambient air, wherein a ratio T/(√S)≧0.17, where T is thickness of said thermal spreader and (√S) is square root of the surface area of the first surface of said thermal spreader.

5. The electronic system of claim 4, wherein the substrate is a circuit board.

6. The electronic system of claim 4, wherein said electronic component is selected from the group consisting of a microprocessor and a graphics processor.

7. The electronic system of claim 4, wherein the system is selected from the group consisting of a personal computer and media center.

8. An electronic system comprising: a substrate; an electronic component mounted on the substrate; water cooler for an electronic component comprising: (1) a thermal spreader having a first surface to be thermally coupled to an electronic component and an opposing second surface; (2) a water block thermally coupled to said second surface of the thermal spreader to transfer a heat from said thermal spreader; (3) a radiator connected with water block by water pipes; (4) a fan for supplying radiator with ambient air; and (5) a pump for forcing water through the cooling circuit consisting of the water block and the radiator, said pump is connected by water pipes with the water block and the radiator, wherein a ratio T/(√S)≧0.17, where T is thickness of said thermal spreader and (√S) is square root of the surface area of the first surface of said thermal spreader.

9. The electronic system of claim 8, wherein the substrate is a circuit board.

10. The electronic system of claim 8, wherein said electronic component is selected from the group consisting of a microprocessor and a graphics processor.

11. The electronic system of claim 8, wherein the system is selected from the group consisting of a personal computer and media center.
